(19) United States
(12) Patent Application Publication
(10) Pub. No.: US 2006/0043605 A1
(43) Pub. Date: Mar. 2, 2006

(54) Semiconductor device

(75) Inventors: Yasuhiro Naka, Hitachinaka (JP); Tomio Iwasaki, Tsukuba (JP); Hidekazu Okuda, Takasaki (JP); Yuji Fujii, Tamamura (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Renesas Technology Corp., Tokyo (JP)

(21) Appl. No.: 11/172,207

(22) Filed: Jun. 29, 2005

(30) Foreign Application Priority Data
Sep. 2, 2004 (JP) 2004-255531

(51) Int. Cl. H01L 23/48

(52) U.S. Cl. 257/779; 257/737

(57) ABSTRACT

To prevent peeling-off of a film in a solder connection pad of a semiconductor device, which peeling-off may occur due to thermal load and so on in the manufacture process, a pad structure is adopted in which a Cr film good in adhesiveness to either of a Ti film or Ti compound film and a Ni film (or a Cu film) is interposed between the Ti film or Ti compound film formed on a silicon or silicon oxide film, and the Ni film (or the Cu film) to be connected to solder. Further, to prevent peeling-off at the interface between the Ti film or Ti compound film and the silicon oxide film, the Cr film is formed in a larger area than the Ti film or Ti compound film.

### BACKGROUND OF THE INVENTION

The present invention relates to a semiconductor device having a connection pad (an electrode pad, a land, or an external terminal) for connection using solder.

Attendant upon a recent increase in requirement of high-density packaging of semiconductor devices, connection methods of semiconductor devices are changing from conventional connection methods by wire bonding as shown in FIG. 11 to connection methods by flip chips as shown in FIG. 12. Because a space provided for disposing wires in the case of wire bonding connection becomes unnecessary in the case of flip chip connection, packaging into a space having a smaller area and a smaller vertical length becomes possible. Further, because the case of the flip chip connection is shorter in electrical transmission path, it is advantageous also from the viewpoint of electrical characteristics. In the case of the flip chip connection, solder is normally used for the connection.

In FIGS. 11 and 12, reference numeral 6 denotes a silicon substrate; reference numeral 7 denotes an insulating film; reference numeral 8 denotes a connection pad; reference numeral 9 denotes an insulating film; reference numeral 10 denotes a bonding wire; reference numeral 11 denotes an adhesive; reference numeral 12 denotes a connection pad; reference numeral 13 denotes a mounting substrate; reference numeral 14 denotes a connection pad; reference numeral 15 denotes a connection pad; and reference numeral 16 denotes a solder layer.

In the case of conventional wire bonding connection, the structure of a connection pad is as shown in FIG. 13. That is, it is a structure in which an Al pad superior in adhesiveness to Au as a wire material is formed on the silicon substrate 6 and a silicon oxide film 3 of a chip. A barrier film 2 made of a Ti film 2 or a Ti compound film is interposed between the silicon substrate 6 and silicon oxide film 3 and the Al film 17 in order to prevent Al in the Al film 17 from diffusing into the silicon substrate 6 and silicon oxide film 3. In the case of flip chip connection using solder, however, because connectivity between the Al film 17 and solder is bad, a Ni film or a Cu film good in connectivity to solder must be formed as an underlayer film of solder. For example, a connection pad of a semiconductor device disclosed in JP-A-6-84919 has a structure in which a Cu—Ni alloy film is formed on an Al film (an Al electrode).

Because either of the Cu film and the Ni film is bad in adhesiveness to the Ti film or the Ti compound film, it is difficult to form the Cu film and the Ni film directly on the Ti film or the Ti compound film. For this reason, normally, also as described in JP-A-6-84919, after an Al pad (an Al film) is formed on the Ti film or the Ti compound film, Cu plating is applied and further Ni plating is applied on the Cu plating so as to prevent Cu from diffusing into solder. Besides, in JP-A-6-84919, for simplifying the process, not a Cu film and a Ni film are formed separately but a Cu—Ni alloy film is formed in a lump. Because adhesiveness between the Al film and the Cu film is relatively high, it can be said that this is a structure better than a structure in which the Cu film and the Ni film are formed directly on the Ti film or the Ti compound film. However, high thermal stress may be generated in accordance with a thermal history in the manufacture process or the thickness of films such as the Cu film, the Ni film, and insulating films, and there is a fear that peeling-off may occur at the interface between the Cu film and Ni film and the Al film or the interface between the Al film and the Ti film or Ti compound film. In addition, because adhesiveness between the Ti film or Ti compound film and the silicon oxide film is poor, it is desirable to take a measure for this portion.

### BRIEF SUMMARY OF THE INVENTION

An object of the present invention is to prevent the above films from peeling off.

The above and other objects and novel features of the present invention will be apparent from the description of this specification and the accompanying drawings.

A summary of a representative feature of the present invention will be briefly described as follows.

In order to prevent peeling off as described above, the present invention is characterized in that Ni plating (a Ni film) is applied directly on an Al pad (an Al film) without Cu plating being interposed, or a Cr film is used in place of the Al film.

FIG. 1 is a graph showing results of comparison of adhesiveness of a Cu film to a Ti film or Ti compound film, an Al film, and a Cr film.

FIG. 2 is a graph showing results of comparison of adhesiveness of a Ni film to a Ti film or Ti compound film, an Al film, and a Cr film.

FIG. 3 is a graph showing results of comparison of adhesiveness of a Ti film or Ti compound film to an Al film and a Cr film.

The adhesive force shown in FIGS. 1 to 3 shows values of molecular binding energy obtained by molecular dynamics calculation, when the adhesive force between the Cu film and the Al film (Cu/Al) is considered to be one. From FIGS. 1 to 3, it is apparent that the Ni film is higher in adhesiveness to the Al film than the Cu film. Higher adhesiveness can be ensured by removing the Cu film, and the manufacture process can be simplified by a method simpler than JP-A-6-84919. Further, it is apparent from FIGS. 1 to 3 that the Cr film has adhesiveness higher than the Al film in coupling with any of the Cu film, the Ni film, and the Ti film or Ti compound film. From FIGS. 1 to 3, the Al film is inferior in adhesiveness to the Cr film. However, because the Al film is soft as its Young's modulus is about 25% of that of the Cr film, the Al film can be expected to have an effect as a stress buffering layer.

Next, adhesiveness to a silicon oxide film will be discussed. As the adhesive force of a silicon oxide film to a Ti film or Ti compound film, an Al film, and a Cr film (as numerical values when the adhesive force between Cu/Al is considered to be one) shown in FIG. 4, the adhesive force between the Cr film and the silicon oxide film is higher than the adhesive force between the Ti film or Ti compound film and the silicon oxide film. Therefore, by a structure in which a Cr film is formed in an area larger than a Ti film or Ti compound film so as to protect the ends of bonding between the Ti film or Ti compound film and the silicon oxide film, which ends may be start points of peeling off, the Ti film or Ti compound film can be prevented from peeling off. Also in the case that an Al film is used in place of the Cr film, because the Al film has a low Young's modulus and can be expected to have a stress buffering effect, it is thinkable that the Ti film or Ti compound film can be prevented from peeling off likewise by forming the Al film in an area larger than the Ti film or Ti compound film.

Other objects, features and advantages of the invention will become apparent from the following description of the embodiments of the invention taken in conjunction with the accompanying drawings.

### BRIEF DESCRIPTION OF THE SEVERAL VIEWS OF THE DRAWING

FIG. 1 is a graph showing the adhesive force of a Cu film to each of a Ti film or Ti compound film, an Al film, and a Cr film;

FIG. 2 is a graph showing the adhesive force of a Ni film to each of a Ti film or Ti compound film, an Al film, and a Cr film;

FIG. 3 is a graph showing the adhesive force of a Ti film or Ti compound film to each of an Al film and a Cr film;

FIG. 4 is a graph showing the adhesive force of a silicon oxide film to each of a Ti film or Ti compound film, an Al film, and a Cr film;

FIG. 5 is a schematic sectional view showing a connection pad portion of a semiconductor device according to a first embodiment of the present invention;

FIG. 6 is a schematic sectional view showing a connection pad portion of a semiconductor device according to a second embodiment of the present invention;

FIG. 7 is a schematic sectional view showing a connection pad portion of a semiconductor device according to a third embodiment of the present invention;

FIG. 8 is a schematic sectional view showing a connection pad portion of a semiconductor device according to a fourth embodiment of the present invention;

FIG. 9 is a schematic sectional view showing a connection pad portion of a semiconductor device according to a fifth embodiment of the present invention;

FIGS. 10A and 10B are views showing a general construction of an electronic device in which a semiconductor device according to a sixth embodiment of the present invention has been mounted on a mounting substrate (10A is a schematic sectional view and 10B is a schematic sectional view in which part of 10A is enlarged);

FIG. 11 is a schematic sectional view showing a state wherein a semiconductor device has been mounted by a conventional wire bonding method;

FIG. 12 is a schematic sectional view showing a state wherein a semiconductor device has been mounted by a conventional flip chip method; and

FIG. 13 is a schematic sectional view showing a connection pad portion of a semiconductor device to be mounted by a conventional wire bonding method.

### DETAILED DESCRIPTION OF THE INVENTION

Hereinafter, embodiments of semiconductor devices having solder connection pad structures of the present invention will be described in detail.

### Embodiment 1

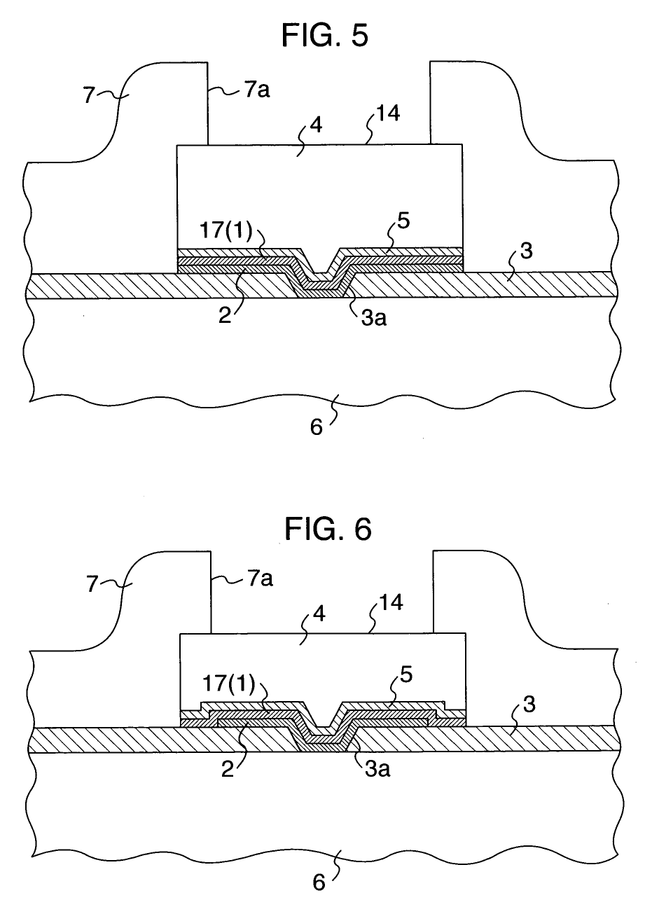

FIG. 5 is a schematic sectional view showing a portion around a connection pad of a semiconductor device according to a first embodiment of the present invention.

As shown in FIG. 5, the semiconductor device of this embodiment 1 has a construction including a silicon substrate 6 made of, for example, single crystal silicon, as a semiconductor substrate; a silicon oxide film 3 provided, for example, as an insulating film, on a principal surface of the silicon substrate 6; a connection pad 14 provided on the silicon oxide film 3; an insulating film 7 provided on the principal surface of the silicon substrate 6 so as to cover the periphery of the connection pad 14; and a bonding opening 7a formed on the connection pad 14 by removing part of the insulating film 7.

Although not shown, a power transistor, for example, called power MISFET (Metal Insulator Semiconductor Field Effect Transistor), is installed in the semiconductor device of this embodiment 1. To obtain high power, the power MISFET has a construction in which a plurality of fine pattern MISFETs (transistor cells) are connected in parallel. The fine pattern MISFETs are formed on the principal surface of the silicon substrate 6.

The connection pad 14 has a construction including a barrier film (conductive film) 2 containing Ti or a Ti compound as its principal ingredient and provided on the silicon oxide film 3; an Al film 17 containing Al as its principal ingredient and provided on the barrier film 2; a Ni film 5 containing Ni as its principal ingredient and provided on the Al film 17; and a Ni film 4 containing Ni as its principal ingredient and provided on the Ni film 5. The barrier film 2 of the connection pad 14 is formed so as to cover the interior surface of a contact hole 3a formed by removing part of the silicon oxide film 3. The barrier film 2 is electrically and mechanically connected to the silicon substrate 6 under the silicon oxide film 3 through the contact hole 3a.

The connection pad 14 can be obtained in the manner that part of the silicon oxide film 3 is removed by a wet or dry etching method to form the contact hole 3a; then the barrier film 2 made of Ti or a Ti compound is formed by, for example, a sputtering method, on the silicon oxide film 3 including the interior of the contact hole 3a; then the Al film 17 is formed on the barrier film 2 by, for example, a sputtering method; then the Ni film 5 is formed on the Al film 17 by, for example, a sputtering method; and then the Ni film 4 is formed on the Ni film 5 by, for example, a plating method.

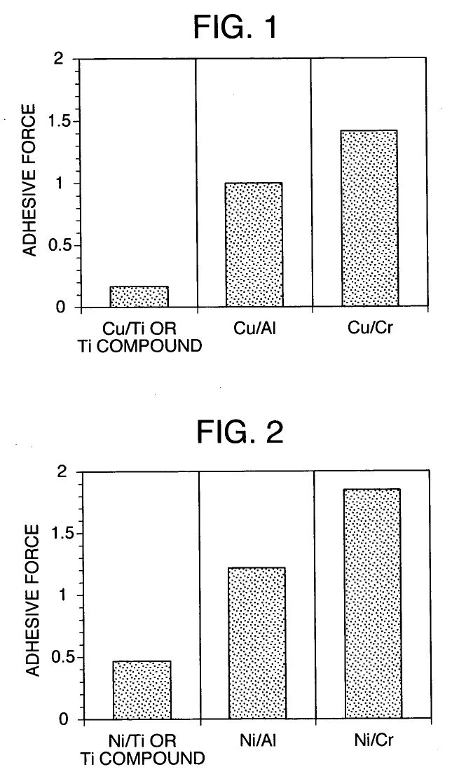

In this embodiment 1, the connection pad 14 has a structure in which the Ni films (5 and 4) are formed directly on the Al film 17 without any Cu film being interposed. As shown in FIGS. 1 and 2, the adhesiveness between a Ni film and an Al film is higher than the adhesiveness between a Ni film and a Cu film. Therefore, by forming the Ni film directly on the Al film, higher adhesiveness can be ensured. This can prevent peeling-off of a film in the connection pad 14, which may occur due to thermal load and so on in the manufacture process. In addition, by exclusion of a Cu film, the manufacture process can be simplified by a method simpler than the technique disclosed in JP-A-6-84919.

The connection pad 14 of this embodiment 1 has a structure in which a Ni sputtering film (the Ni film 5 formed by a sputtering method) is interposed between the Al film 17 and a Ni plating film (the Ni film 4 formed by a plating method). However, the Ni sputtering film (Ni film 5) may not be provided. But, because the adhesiveness between the Al film 17 and the Ni plating film (Ni film 4) is enhanced by provision of the Ni sputtering film (Ni film 5), it is preferable that the Ni sputtering film (Ni film 5) is interposed between the Al film 17 and the Ni plating film (Ni film 4) as in this embodiment 1.

Although an example wherein the Al film 17 is provided on the barrier film 2 has been described in this embodiment 1, a Cr film 1 containing Cr as its principal ingredient may be provided in place of the Al film 17. In this case, because the adhesiveness between a Ni film and the Cr film 1 is higher than the adhesiveness between the Ni film and the Al film 17 as shown in FIG. 2, and the adhesiveness between a Ti film or Ti compound film and the Cr film 1 is higher than the adhesiveness between the Ti film or Ti compound film and the Al film 17 as shown in FIG. 3, peeling-off of a film in the connection pad 14 can be further prevented.

### Embodiment 2

FIG. 6 is a schematic sectional view showing a portion around a connection pad of a semiconductor device according to a second embodiment of the present invention.

The connection pad 14 of this embodiment 2 has fundamentally the same construction as that of the above-described embodiment 1, but the former differs from the latter in the below-described feature.

That is, as shown in FIG. 6, the connection pad 14 of this embodiment 2 has a structure in which the Al film 17 is formed in a larger area than the barrier film (film containing Ti or a Ti compound as its principal ingredient) 2 to protect the edge of bond between the barrier film 2 and the silicon oxide film 3, which may work as a start point of peeling-off; in other words, the barrier film 2 is covered with the Al film and the Al film 17 is bonded to the silicon oxide film 3 around the barrier film 2. By adopting this structure, peeling-off at the interface between the film containing Ti or a Ti compound as its principal ingredient, and the silicon oxide film 3 can be prevented because the Al film is soft as its Young's modulus is about 25% of that of a Cr film, and thus it can be expected to have an effect as a stress buffering layer.

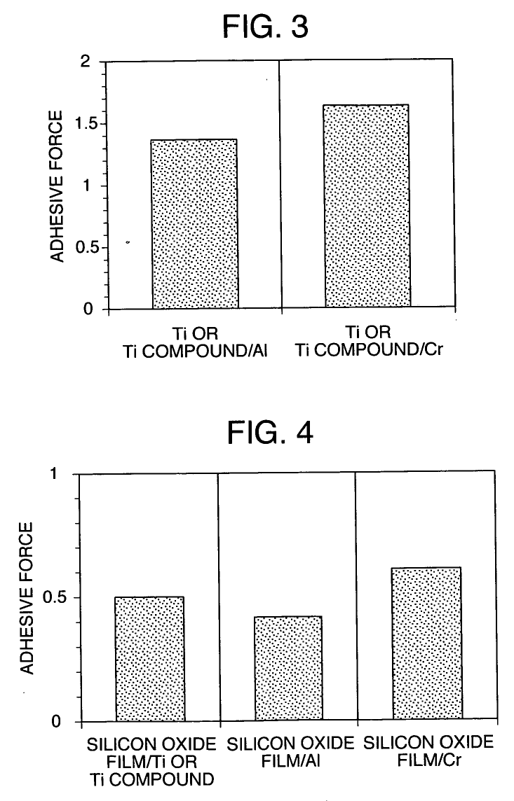

Although an example wherein the Al film 17 is provided on the barrier film 2 has been described in this embodiment 2, a Cr film 1 may be provided in place of the Al film 17 in the present invention. In this case, because the adhesiveness between the Cr film 1 and the silicon oxide film 3 is higher than the adhesiveness between a film containing Ti or a Ti compound as its principal ingredient (the barrier film 2) and the silicon oxide film 3 as shown in FIG. 4, peeling-off at the interface between the film containing Ti or a Ti compound as its principal ingredient (the barrier film 2) and the silicon oxide film 3 can be prevented by a structure in which the Cr film 1 is formed in a larger area than the film containing Ti or a Ti compound as its principal ingredient (the barrier film 2) to protect the edges of bond between the barrier film 2 and the silicon oxide film 3, which may work as a start point of peeling-off.

### Embodiment 3

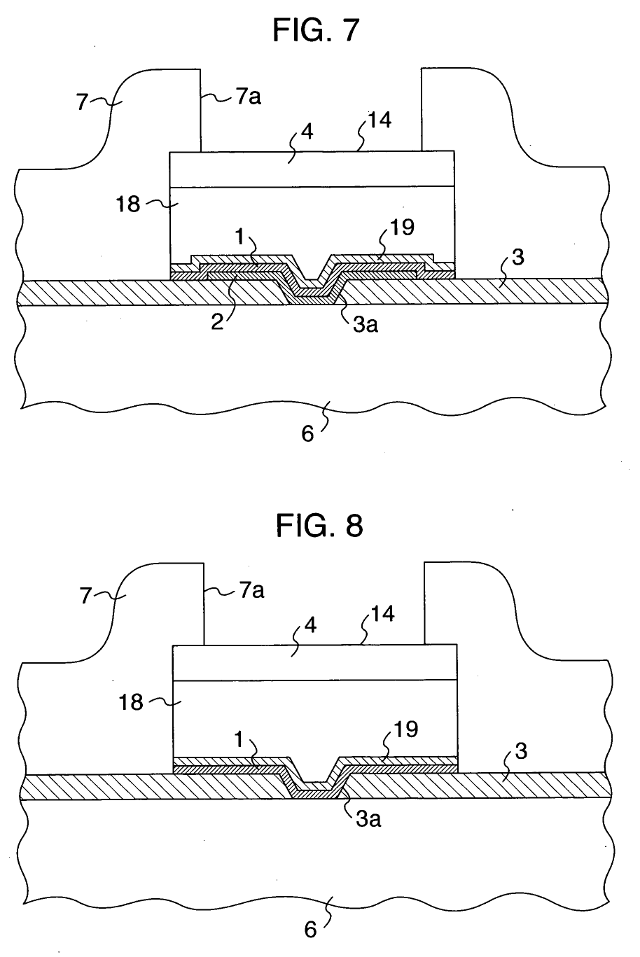

FIG. 7 is a schematic sectional view showing a portion around a connection pad of a semiconductor device according to a third embodiment of the present invention.

Because a Ni plating film (a Ni film formed by a plating method) is high in intrinsic stress, the wafer may be largely bent in the manufacture process, which may be in question. Contrastingly, the intrinsic stress of a Cu plating film (a Cu film formed by a plating method) is low as a half to about 30% of that of the Ni plating film. Therefore, from the viewpoint of prevention of bend of a wafer, it is advantageous to use the Cu plating film in place of the Ni plating film. In the case of using the Cu plating film, a Cr film is preferably used as the underlayer film of the Cu plating film in consideration of adhesiveness. In the third embodiment shown in FIG. 7, in consideration of the above, a Cu plating film 18 is formed on the Cr film 1. To increase adhesiveness, a Cu sputtering film 19 (a Cu film formed by a sputtering method) is preferably interposed between the Cu plating film and the Cr film 1. However, in the case that solder is applied directly on the Cu plating film, Cu may diffuse into the solder to make an alloy, and as a result, the strength of the connection may be reduced. To prevent this, as shown in FIG. 7, a Ni plating film (the Ni film 4) is preferably formed on the Cu plating film 18.

To prevent peeling-off at the interface between the film containing Ti or a Ti compound as its principal ingredient (the barrier film 2) and the silicon film 3, like the second embodiment, the Cr film 1 is preferably formed in a larger area than the film containing Ti or a Ti compound as its principal ingredient (the barrier film 2).

### Embodiment 4

FIG. 8 is a schematic sectional view showing a portion around a connection pad of a semiconductor device according to a fourth embodiment of the present invention.

A film containing Ti or a Ti compound as its principal ingredient is not high in adhesiveness to a silicon oxide film. Contrastingly, as shown in FIG. 4, a Cr film is higher in adhesiveness to a silicon oxide film than the film containing Ti or a Ti compound as its principal ingredient. Because the Cr film can be expected to have an effect of preventing Cu or Ni from diffusing into a silicon or silicon oxide film, like a Ti film or Ti compound film, there is possibility that the Ti film or Ti compound film can be omitted. Because the interface resistance with silicon varies when the Ti film or Ti compound film is omitted, examination on this point must be made. However, if the Ti film or Ti compound film can be omitted, adhesiveness to the silicon oxide film 3 can be improved, and further the manufacture process can be simplified. Thus, it can be said that a structure in which the Cr film 1 is in direct contact with the contact portion of the silicon substrate 6 as in the fourth embodiment shown in FIG. 8, is an advantageous structure.

This structure can be applied also to a case wherein a Cu plating film is used in place of the Ni plating film, or a case wherein a Cu plating film is interposed as the underlayer of the Ni plating film, for preventing a wafer from being bent. FIG. 8 shows an example wherein a Cu plating film 18 is interposed as the underlayer of a Ni plating film (the Ni film 4).

### Embodiment 5

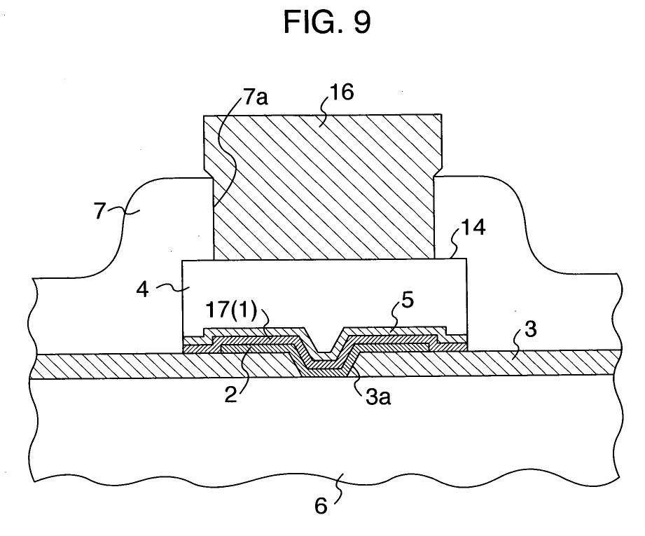

FIG. 9 is a schematic sectional view showing a portion around a connection pad of a semiconductor device according to a fifth embodiment of the present invention. In the case that a semiconductor device of the present invention is connected to a connection object such as a mounting substrate, a method is thinkable in which a solder paste material is applied to a connection pad on the mounting substrate, the semiconductor device is put on, and then reflow is performed. However, to ensure a sufficient height for connection by solder, it is desirable that solder has been applied in advance to the connection pad on the semiconductor device. In this case, a method is also possible in which not the paste material but only a flux material is applied to the connection pad on the mounting substrate. FIG. 12 shows an example wherein a solder layer 16 is provided on the connection pad 14 of the second embodiment. The solder layer 16 is formed in the manner that solder paste is applied to the connection pad 14 by screen printing and then it is heated to reflow. Otherwise, a method is also thinkable in which solder paste and a flux material are applied to the connection pad 14; then a solder ball is put on; and then the solder paste and the flux material are heated to reflow.

Likewise, it is desirable to apply solder in advance also in the first, third, and fourth embodiments.

### Embodiment 6

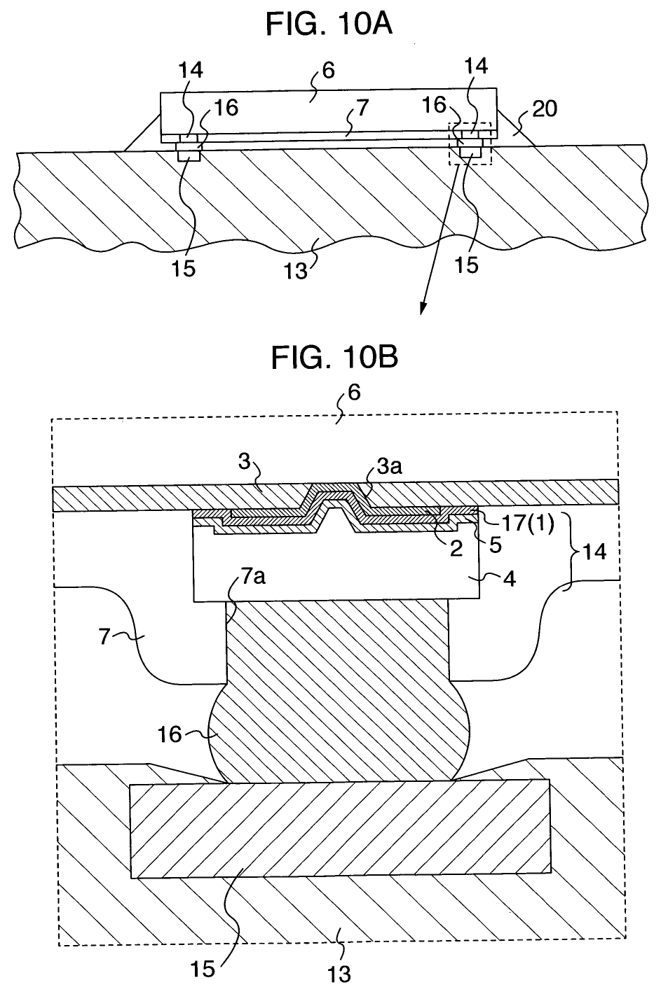

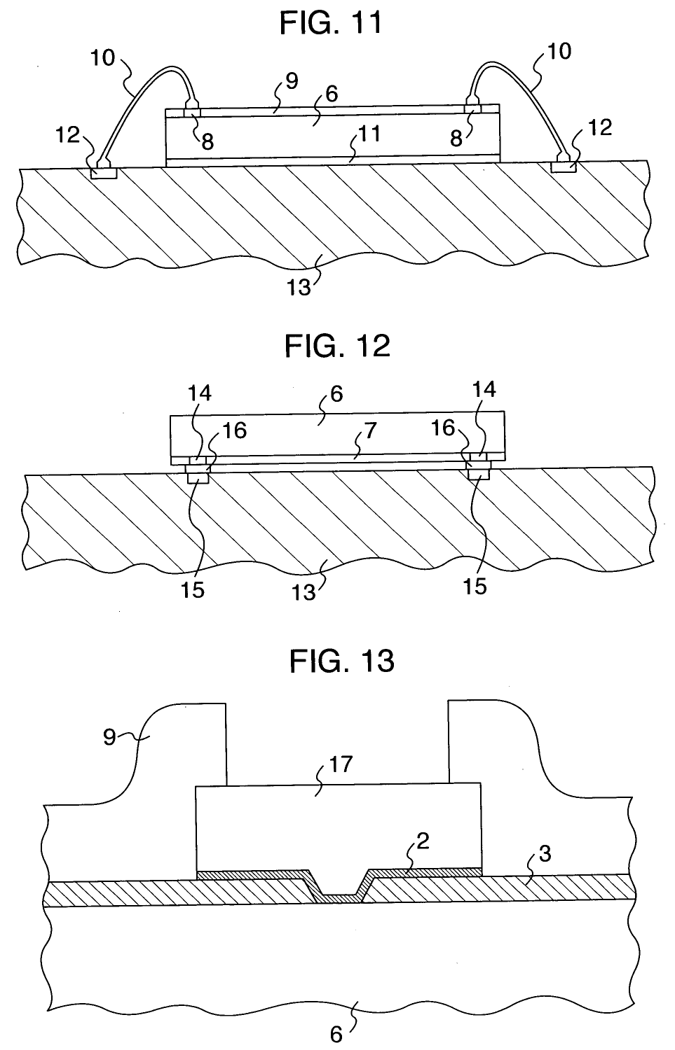

FIGS. 10A and 10B are views showing a general construction of an electronic device in which a semiconductor device according to a sixth embodiment of the present invention has been mounted on a mounting substrate (10A is a schematic sectional view and 10B is a schematic sectional view in which part of 10A is enlarged). FIGS. 10A and 10B schematically show a form after a semiconductor device of the present invention is connected to a connection object such as a mounting substrate. By way of example, FIGS. 10A and 10B show a form in which the semiconductor device of the second embodiment has been connected to a mounting substrate 13.

As shown in FIGS. 10A and 10B, a solder paste material is applied to a connection pad 15 on the mounting substrate 13; then the semiconductor device is put on so that its connection pad 14 is opposed to the connection pad 15 on the mounting substrate 13; and then the semiconductor device is connected by being heated to reflow. In the case of connecting a semiconductor device in which solder has been applied in advance to the pad of the semiconductor device, as in the fifth embodiment, it is also possible that not the solder paste material but only a flux material is applied to the connection pad 15 on the mounting substrate 13. In order to ensure reliability of connection by solder, a resin 20 may be interposed between the semiconductor device and the mounting substrate 13.

Hereinbefore, the invention made by the present inventors have been specifically described on the basis of the above embodiments. However, it is of course that the present invention is never limited to the above embodiments, and various changes, alternations, and modifications can be made therein without departing the scope of the invention.

It should be further understood by those skilled in the art that although the foregoing description has been made on embodiments of the invention, the invention is not limited thereto and various changes and modifications may be made without departing from the spirit of the invention and the scope of the appended claims.

1. A semiconductor device having a connection pad for connection using solder,
the connection pad comprising:
a first film containing Ti or a Ti compound as its principal ingredient;
a second film formed on the first film and containing Al as its principal ingredient; and
a third film formed on the second film and containing Ni as its principal ingredient.

2. A semiconductor device having a connection pad for connection using solder,
the connection pad comprising:
a first film containing Ti or a Ti compound as its principal ingredient;
a second film formed on the first film and containing Cr as its principal ingredient; and
a third film formed on the second film and containing Ni as its principal ingredient.

3. A semiconductor device having a connection pad for connection using solder,
the connection pad comprising:
a first film containing Ti or a Ti compound as its principal ingredient;
a second film formed on the first film and containing Cr as its principal ingredient; and
a third film formed on the second film and containing Cu as its principal ingredient.

4. A semiconductor device having a connection pad for connection using solder,
the connection pad comprising:
a first film containing Ti or a Ti compound as its principal ingredient;
a second film formed on the first film and containing Cr as its principal ingredient;
a third film formed on the second film and containing Cu as its principal ingredient; and
a fourth film formed on the third film and containing Ni as its principal ingredient.

5. The semiconductor device according to any one of claims 1 to 4, wherein the first film of the connection pad is formed on a silicon oxide film, and the second film of the connection pad is formed in a larger area than the first film.

6. The semiconductor device according to claim 5, wherein the first film of the connection pad is formed so as to cover an interior surface of a contact hole formed by removing part of the silicon oxide film, and the connection pad is electrically connected to a semiconductor substrate under the silicon oxide film through the contact hole.

7. The semiconductor device according to any one of claims 1 to 4, further comprising:
a semiconductor substrate;
an insulating film formed on the semiconductor substrate so as to cover a periphery of the connection pad; and
a bonding opening formed on the connection pad by removing part of the insulating film.

8. The semiconductor device according to any one of claims 1 to 4, further comprising a solder layer formed on the connection pad.

9. An electronic device in which the semiconductor device according to any one of claims 1 to 4 is mounted on a mounting substrate with solder being interposed between the connection pad of the semiconductor device and a connection pad of the mounting substrate.

10. A semiconductor device having a connection pad for connection using solder, the connection pad being formed on a silicon oxide film,
the connection pad comprising:
a first film containing Cr as its principal ingredient; and
a second film formed on the first film and containing Ni as its principal ingredient.

11. A semiconductor device having a connection pad for connection using solder, the connection pad being formed on a silicon oxide film, the connection pad comprising:
a first film containing Cr as its principal ingredient; and
a second film formed on the first film and containing Cu as its principal ingredient.

12. A semiconductor device having a connection pad for connection using solder, the connection pad being formed on a silicon oxide film,
the connection pad comprising:
a first film containing Cr as its principal ingredient;
a second film formed on the first film and containing Cu as its principal ingredient; and
a third film formed on the second film and containing Ni as its principal ingredient.

13. The semiconductor device according to any one of claims 10 to 12, further comprising:
a semiconductor substrate;
an insulating film formed on the semiconductor substrate so as to cover a periphery of the connection pad; and
a bonding opening formed on the connection pad by removing part of the insulating film.

14. The semiconductor device according to any one of claims 10 to 12, further comprising a solder layer formed on the connection pad.

15. An electronic device in which the semiconductor device according to any one of claims 10 to 12 is mounted on a mounting substrate with solder being interposed between the connection pad of the semiconductor device and a connection pad of the mounting substrate.
